(19) United States
(12) Patent Application Publication
(10) Pub. No.: US 2009/0155730 A1
(43) Pub. Date: Jun. 18, 2009

(54) METHOD FOR MANUFACTURING STORAGE MEDIUM AND APPARATUS FOR MANUFACTURING INFORMATION STORAGE MASTER DISC

(75) Inventor: Toshihiko SHIRASAGI, Shizuoka (JP)

Correspondence Address: ROBERT J. DEPKE;LEWIS T. STEADMAN, ROCKEY, DEPKE & LYONS, LLC, SUITE 5450 SEARS TOWER, CHICAGO, IL, 60606-6306, US

(73) Assignee: Sony Corporation, Tokyo (JP)

(21) Appl. No.: 12/323,220

(22) Filed: Nov. 25, 2008

(30) Foreign Application Priority Data
Dec. 14, 2007 (JP) 2007-323653

(51) Int. Cl. G03F 7/20; G03B 27/52

(52) U.S. Cl. 430/321; 355/27

(57) ABSTRACT

A method for manufacturing an information storage medium in which information is stored as a concave-convex pattern includes forming an inorganic-resist master disc by depositing on a substrate an inorganic resist layer reactive to thermal reaction associated with laser beam irradiation, recording on the inorganic-resist master disc by differentiating depths of thermal reaction portions in the inorganic resist layer by inputting information to be stored in the information storage medium and varying power of the laser beam striking the inorganic-resist master disc over at least three levels according to the input information, forming an information storage master disc having a concave-convex pattern in the inorganic resist layer by developing the recorded inorganic-resist master disc, forming a stamper to which the concave-convex pattern formed on the inorganic resist layer has been transferred on the basis of the information storage master disc, and forming the information storage medium using the stamper.

### CROSS REFERENCES TO RELATED APPLICATIONS

The present invention contains subject matter related to Japanese Patent Application JP 2007-323653 filed in the Japanese Patent Office on Dec. 14, 2007, the entire contents of which are incorporated herein by reference.

### BACKGROUND OF THE INVENTION

1. Field of the Invention

The present invention relates to a method for manufacturing an information storage medium in which information is stored by creating a concave-convex pattern, and an apparatus for manufacturing an information storage master disc on which information is recorded through exposure, used to manufacture the information storage medium.

2. Description of the Related Art

Optical disc recording media are available as information storage media in which information is stored by creating a concave-convex pattern. In common optical disc recording media, such as compact discs (CDs), digital versatile discs (DVDs), and blu-ray discs (BDs), information is stored by a combination of pits and lands. That is, information is stored as the presence/absence of grooves that serve as the pits.

An effort has been made to store information by making the depths of grooves formed in an optical disc recording medium different from each other. It aims at increasing the storage capacity compared to the case in which information is stored as the presence/absence of the grooves, i.e., pits and lands, by enabling information to be stored in the depth direction too.

Japanese Unexamined Patent Application Publication No. 8-227538 discloses, as such an effort, a configuration in which a master disc including a plurality of photoresist layers having different sensitivities is irradiated with laser beams having powers corresponding to the depths of grooves to be formed, whereby the depths of the grooves are controlled. For example, when there are a lower photoresist layer and an upper photoresist layer, a material with lower sensitivity is selected for the lower photoresist layer. Then, the photoresist layers are irradiated with a laser beam of power 0 when a groove of depth 0 (that is, a land) is to be formed, with a laser beam of power 1 larger than power 0 when a groove of depth 1 is to be formed, and with a laser beam of power 2 larger than power 1 when a groove of depth 2 is to be formed. As a result, recording is performed such that neither photoresist layer reacts when irradiated with the laser beam of power 0, only the upper photoresist layer reacts when irradiated with the laser beam of power 1, and both photoresist layers react when irradiated with the laser beam of power 2. Thus, it is possible to control the depths of the grooves to be formed.

Hologram storage media are also information storage media in which information is stored by creating a concave-convex pattern. In the hologram storage media, a hologram serving as a diffraction grating is formed (stored) by differences in optical path lengths caused by differences in depths of grooves.

When a hologram is stored as an image, for example, a hologram storage medium has to be able to provide finer gradation expression to reproduce the details of the image, such as the smoothness of a curved line. More specifically, it is desirable that the hologram storage medium be capable of express at least about 16 gradations in the depth direction.

In a related art method for manufacturing a storage medium in which a hologram is stored, a process including resist layer formation, exposure (development), and dry etching is repeatedly performed, as shown in FIGS. 8A to 8D.

As shown in FIG. 8A, in this case, first, a resist layer is formed on a substrate and is exposed (developed) through a mask. Then, as shown in FIG. 8B, dry etching is performed to form grooves in the first layer. In this method, the first layer is the deepest layer. Thus, in the first layer, only the portions where the deepest grooves are formed are exposed.

Then, as shown in FIG. 8C, a resist layer serving as a second layer is formed on the first layer and is exposed through a mask. Finally, as shown in FIG. 8D, the second layer is etched. By repeatedly performing these steps, grooves of different depths are formed.

In another related art method for forming grooves of different depths, the acceleration voltage of an electron beam is varied.

FIGS. 9A to 9C schematically show this method.

As shown in FIG. 9A, this method uses a master disc made of a silicon (Si) substrate and a spin on glass (SOG) resist film formed thereon. The SOG master disc is exposed while the acceleration voltage is varied (FIG. 9B), and is then developed (FIG. 9C). A hydrofluoric acid buffer solution is used to develop the SOG master disc.

In this method, the depth by which the electron beam penetrates the SOG resist film varies according to the acceleration voltage. Thus, the master disc after being developed has grooves of different depths according to the acceleration voltages varied during the exposure.

For details of the method shown in FIGS. 9A to 9C, see MATERIAL STAGE Vol 6, No. 8 2006, Jun Taniguchi “An overview and perspective of the hologram forming technique using nanoimprint”.

### SUMMARY OF THE INVENTION

As has been described, although various methods for forming grooves of different depths have been developed, these methods have the following problems.

For example, in the method disclosed in Japanese Unexamined Patent Application Publication No. 8-227538, it is necessary to deposit multiple resists having different sensitivities. However, in sputtering deposition, it is very difficult to change the deposition condition in a multi-step manner from the standpoint of the process. Therefore, the number of films is limited to a few.

Even if such film deposition is possible, it is very difficult to significantly differentiate the sensitivities among the films to be deposited.

In any case, in the method disclosed in Japanese Unexamined Patent Application Publication No. 8-227538, a plurality of resist layers have to be deposited, resulting in an increase in the number of steps.

The method shown in FIG. 8 has a problem in that, when resist layers are formed on a processed substrate and are exposed, even a slight misalignment of the mask allows unintended portions to be etched and intended portions to be left unetched in the subsequent etching step, whereby an error in the shape tends to occur. That is, this method lacks the dimensional accuracy.

In addition, because this method involves many steps, the initial cost, running cost, and labor cost associated with the manufacturing apparatus are high. Furthermore, because this method involves many steps, the operation time of the manufacturing apparatus necessary to manufacture the products is long. Accordingly, this method exerts a large impact on the environment.

The method shown in FIGS. 9A to 9C imposes the tight restriction that, because the acceleration voltage is varied, an object to be irradiated with a beam has to be placed in a vacuum environment as in the case of a scanning electron microscope. Because of such limitation, the size of a master disc has to be such that it can be placed in a vacuum chamber.

The method shown in FIGS. 9A to 9C also has problems in that, in manufacturing a master disc, the master disc has to be baked at a temperature as high as 300° C. after a liquid serving as a SOG film is applied thereto, and that a hydrofluoric acid buffer solution, which is a dangerous chemical, has to be used to develop exposed portions.

Hydrofluoric acid imposes a considerable strain on human health and the environment, and the use thereof is strictly restricted by various applicable laws. Examples of such applicable laws include the poisonous and deleterious substances control law (poison), the regulation for prevention of injury by specified chemical substances, the water pollution control law, the air pollution control law, the sewerage law, and the act on confirmation, etc. of release amounts of specific chemical substances in the environment and promotion of improvements to the management thereof (PRTR law).

In addition, because the SOG film is mainly composed of silicon dioxide (SiO₂), a conductive film has to be formed when a metal master disc is formed. Thus, it involves an extra step.

The present invention has been made in view of the above-described problems. According to an embodiment of the present invention, there is provided a method for manufacturing an information storage medium in which information is stored as a concave-convex pattern.

The method includes a step of forming an inorganic-resist master disc by depositing on a substrate an inorganic resist layer reactive to thermal reaction associated with laser beam irradiation.

The method also includes a step of recording on the inorganic-resist master disc by differentiating depths of thermal reaction portions in the inorganic resist layer by inputting information to be stored in the information storage medium and varying power of the laser beam striking the inorganic-resist master disc over at least three levels according to the input information.

The method also includes a step of forming an information storage master disc having a concave-convex pattern in the inorganic resist layer by developing the inorganic-resist master disc having been recorded in the recording step.

The method also includes a step of forming a stamper to which the concave-convex pattern formed on the inorganic resist layer has been transferred on the basis of the information storage master disc.

The method also includes a step of forming the information storage medium using the stamper formed in the stamper forming step.

As described above, in an embodiment of the present invention, information is recorded on the inorganic-resist master disc by irradiation with the laser beam while the power thereof is modulated over three or more levels according to the information to be stored in the storage medium. Accordingly, the information storage master disc obtained after development has a concave-convex pattern of a plurality of depths.

According to an embodiment of the present invention, grooves of different depths can be formed without using multiple resist layers. It is unnecessary to repeatedly perform deposition and etching or to form a plurality of resist layers having different sensitivities. Accordingly, the initial cost, running cost, and labor cost associated with the manufacturing apparatus can be reduced. In addition, because the operation time of the manufacturing apparatus can be reduced, strain on the environment can be reduced.

Furthermore, according to an embodiment of the present invention, a concave-convex pattern of a plurality of depths can be formed in a single step (exposure step). Therefore, degradation in dimensional accuracy due to misalignment of the mask does not occur, whereby a more precise recording becomes possible.

In addition, exposure does not have to be performed in a special environment such as a vacuum state, and it may be performed in a normal atmospheric environment. Therefore, unlike the related art method in which the acceleration voltage is varied, there is no restriction on the size of substrates. Accordingly, it becomes possible to manufacture a large-area storage medium.

Furthermore, an embodiment of the present invention has an advantage in that a material that poses a high risk to human bodies and the environment does not have to be used as an inorganic resist film or a developing solution.

### BRIEF DESCRIPTION OF THE DRAWINGS

FIGS. 1A to 1J show a method for manufacturing an information storage medium according to an embodiment of the present invention;

FIG. 2 shows an internal configuration of an apparatus for manufacturing an information storage master disc according to an embodiment of the present invention;

FIG. 3 shows an internal configuration of a master disc recording unit of the apparatus for manufacturing an information storage master disc according to an embodiment of the present invention;

FIG. 4 shows an exemplary relationship between multi-step control of laser power and the depths of grooves formed in an inorganic-resist master disc;

FIGS. 5A and 5B show groove portions formed when recording is performed by irradiation with a laser beam having small power;

FIGS. 6A and 6B show groove portions formed when recording is performed by irradiation with a laser beam having great power;

FIG. 7 is a graph showing the relationship between the laser power and the depth of the groove portions to be formed;

FIGS. 8A to 8D show a related art method; and

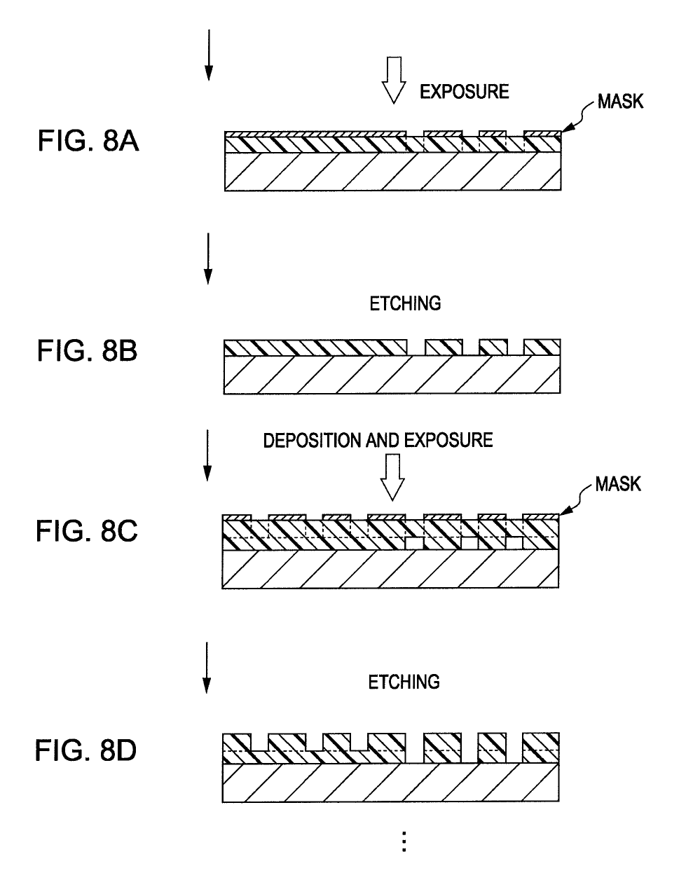

FIGS. 9A to 9C is a diagram for explaining another related art method.

### DESCRIPTION OF THE PREFERRED EMBODIMENTS

Preferred embodiments (hereinafter, “embodiments”) of the present invention will be described below.
1. Manufacturing Process of Disc
2. Configuration of Apparatus for Manufacturing a Master Disc
3. Configuration of Master Disc Recording Unit
4. Exemplary Modulation Processing
5. Modification Example

### 1. MANUFACTURING PROCESS OF DISC

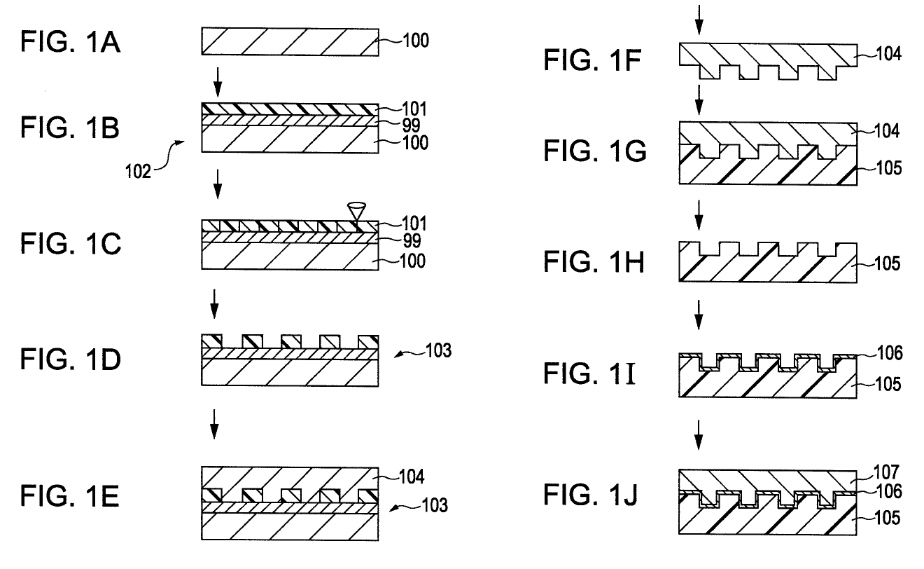

Referring to FIGS. 1A to 1J, a process of manufacturing an information storage medium will be described.

Herein, an “information storage medium” refers to a storage medium in which information is stored as a concave-convex pattern.

A process of manufacturing an information storage medium according to the present embodiment can be roughly classified into a master disc forming step, a recording step (exposure step), a development step, a die (stamper) forming step, and a storage medium forming step.

In the present embodiment, the information storage medium is supposed to be disc-shaped. The following description is directed to the case in which an optical disc containing predetermined data, such as music content or video content, readable by irradiation with light is manufactured.

FIG. 1A shows a master disc forming substrate 100 that constitutes a master disc. First, using a sputtering method, an inorganic resist material is uniformly deposited on the master disc forming substrate 100 to form an inorganic resist layer 101 (a resist layer forming step, shown in FIG. 1B). Thus, an inorganic-resist master disc 102 is formed.

In this embodiment, as a mastering step for forming a master disc, mastering by a phase transition mastering (PTM) method using an inorganic resist material is performed. The resist layer 101 is made of an incomplete oxide of a transition metal, the examples of which include Ti, V, Cr, Mn, Fe, Nb, Cu, Ni, Co, Mo, Ta, W, Zr, Ru, and Ag.

In order to improve the exposure sensitivity of the inorganic resist layer 101, a predetermined intermediate layer 99 may be formed between the substrate 100 and the resist layer 101. Such a state is shown in FIG. 1B. In any case, the resist layer 101 has to be formed on the substrate 100 in an uncovered state, so that it can be reacted to laser beam irradiation during exposure.

The master disc forming substrate 100 includes a Si wafer substrate, and the resist layer 101 is deposited thereon by DC sputtering or RF sputtering.

Although the thickness of the resist layer 101 may be set to any value, the thickness in the range from 10 nm to 80 nm is preferable. In the present embodiment, as will be described below, grooves of several depths will be formed in the resist layer 101. Therefore, the thickness of the resist layer 101 may be set at the most appropriate value according to the number of depths of the grooves, within the range specified above.

Next, the resist layer 101 is selectively exposed according to a signal pattern and is reacted (a resist layer exposure step, shown in FIG. 1C).

This exposure step is performed using an apparatus for manufacturing a master disc (an apparatus for manufacturing an information storage master disc 1), which will be described below. The exposure (recording) operation performed by the apparatus for manufacturing an information storage master disc 1 of this example will be described below.

Then, the resist layer 101 is developed to obtain a master disc 103 (an information storage master disc) on which a predetermined concave-convex pattern is formed (a resist layer developing step, shown in FIG. 1D). More specifically, in this resist layer developing step, the resist layer 101 is developed by a dipping method (immersion) or a method in which a chemical solution is applied to the master disc 102 while the master disc 102 is spun by a spinner.

Examples of the developing solution include an organic alkaline developing solution such as tetramethyl ammonium hydroxide (TMAH) solution and inorganic alkaline developing solutions such as KOH, NaOH, and phosphoric acid solutions.

Next, after the thus formed master disc 103 is rinsed with water, a metal master disc is formed in an electroforming tank (an electroforming step, shown in FIG. 1E). After the electroforming, the master disc 103 and the metal master disc are separated. Thus, a stamper 104 for molding, to which the concave-convex pattern of the master disc 103 has been transferred, is obtained (FIG. 1F). In this embodiment, the material of the metal master disc (stamper 104) is Ni.

To improve the mold releasability, if necessary, the surface of the master disc 103 may be treated with a mold-releasing treatment before it is subjected to the electroforming step shown in FIG. 1E.

The mold releasability may be improved by treating the master disc 103 with any one of the following treatments:

1) The master disc 103 is immersed in an alkaline solution heated to a temperature in the range from 40 to 60° C. for several minutes;

2) The master disc 103 is immersed in an electrolytic alkaline solution heated to a temperature in the range from 40 to 60° C. for several minutes until it is electrolytically oxidized.

3) An oxide film is formed using a method such as reactive ion etching (RIE).

4) A metal-oxide film is formed using a film deposition apparatus.

The mold releasability can also be improved by selecting an inorganic resist material having an oxide composition ratio such that it is easily released from the metal master disc.

After the stamper 104 is formed, the master disc 103 is rinsed with water, dried, and stored. A desired number of the stampers 104 may be repeatedly formed as necessary.

Then, using the stamper 104, a plastic disc substrate 105 made of polycarbonate, which is a thermoplastic, is formed by means of injection molding (FIG. 1G).

After the stamper 104 is removed (FIG. 1H), a reflective film 106 (FIG. 1I) made of, for example, a Ag alloy, and a protective film 107 having a thickness of about 0.1 mm are deposited on the concave-convex surface of the plastic disc substrate 105, whereby an optical disc is formed (FIG. 1J). Thus, an information storage medium in which information is stored as a concave-convex pattern is obtained.

As has been described above, the resist layer 101 of the inorganic-resist master disc 102 is made of an incomplete oxide of a transition metal.

Herein, the term “incomplete oxide of a transition metal” is defined as a compound whose oxide content is shifted to a smaller value than the stoichiometric composition corresponding to the possible valency of the transition metal, that is, a compound such that the oxide content of an incomplete oxide of the transition metal is smaller than the oxide content of the stoichiometric composition corresponding to the possible valency of the transition metal.

Molybdenum trioxide (MoO₃) will be described as an exemplary transition metal oxide. When the oxidation state of MoO₃ is expressed by a composition proportion Mo₁₋ₓOₓ, MoO₃ is a complete oxide at x=0.75 and an incomplete oxide at 0<x<0.75, in which the oxide content is smaller than the stoichiometric composition.

Some transition metals can form oxides having different valencies from one element. In such transition metals, an incomplete oxide refers to a compound whose actual oxide content is smaller than the stoichiometric composition corresponding to the possible valency of the transition metal. For example, molybdenum oxide is also present in the monovalent form (MoO) in addition to the trivalent form (MoO₃), which is the most stable form of molybdenum oxide, described above. When MoO is expressed by a composition proportion Mo₁₋ₓOₓ, at 0<x<0.5, it is an incomplete oxide whose oxide content is smaller than the stoichiometric composition. The valency of a transition metal oxide can be analyzed using a commercially available analyzer.

Such an incomplete oxide of a transition metal absorbs the ultraviolet rays and the visible rays. When irradiated with the ultraviolet rays or the visible rays, the chemical properties of such an incomplete oxide change. Therefore, in spite of the resist being an inorganic one, in the development step, the etching rate is different between exposed portions and unexposed portions. In other words, a so-called selection ratio is obtained. Furthermore, because the grain size of a resist material composed of an incomplete oxide of a transition metal is fine, patterns at the boundaries between unexposed portions and exposed portions are clear. Thus, the resolution is increased.

The property of an incomplete oxide of a transition metal as a resist material changes according to the extent of oxidation. Therefore, the most appropriate extent of oxidation should be selected. For example, an incomplete oxide whose oxide content is considerably smaller than the stoichiometric composition of a complete oxide of a transition metal has problems in that large irradiation power is necessary in the exposure step and in that the development process takes a long time. Therefore, an incomplete oxide whose oxide content is slightly smaller than the stoichiometric composition of the complete oxide of a transition metal is preferable.

As described above, examples of the transition metal used in the resist material include Ti, V, Cr, Mn, Fe, Nb, Cu, Ni, Co, Mo, Ta, W, Zr, Ru, and Ag. Among these transition metals, Mo, W, Cr, Fe, and Nb are especially preferable. In particular, Mo and W are preferable from the standpoint of the possibility of inducing a significant chemical reaction with the ultraviolet rays or the visible rays.

In this embodiment, mastering by a PTM method is performed in the above-described optical disc forming step. The PTM method will be briefly explained below.

For example, when CDs and DVDs are manufactured through a typical mastering method other than the PTM method, first, a photoresist (organic resist) is applied to a master disc. Then, using a mastering apparatus (an apparatus for manufacturing a master disc), a laser beam is emitted from a light source, such as a gas laser, onto the master disc to form an exposure pattern corresponding to pits. At this time, the intensity of the laser beam from the laser beam source, which is a continuous-wave laser, is modulated by an acousto-optical modulator (AOM), for example. The laser beam after being modulated is directed to the master disc by an optical system so that the master disc is exposed. That is, a non return to zero (NRZ) modulation signal, which is an exemplary pit modulation signal, is input to the AOM, and the AOM modulates the intensity of the laser beam in accordance with the pit pattern. Thus, only the pit portions on the master disc are exposed.

Because the exposure of the photoresist is performed through a so-called optical recording, the portions exposed to the laser beam constitute pits. That is, the spot diameter of the laser beam determines the width of the pits.

In contrast, in the PTM method, an inorganic resist is applied to a master disc, and the master disc is irradiated with a laser beam emitted from a semiconductor laser. Then, exposure as thermal recording is performed. That is, application of heat to the master disc along with the irradiation with the laser beam changes the property (i.e., the chemical property) of the inorganic resist, whereby recording marks are formed.

In the PTM method, an incomplete oxide of a transition metal is used for the resist material of the master disc. As mentioned above, an incomplete oxide of a transition metal absorbs the ultraviolet rays and the visible rays. In this respect, it is not necessary to use a special light source, such as an electron beam or an ion beam, as the exposure source. A laser diode used in a typical optical disc apparatus, for example, may be used.

In addition, an incomplete oxide of a transition metal shows a significant change in the chemical property at a portion where the heat is focused, and the width of grooves to be formed is not directly influenced by the diameter of the laser spot. Accordingly, in this respect, the PTM method enables fine grooves to be formed compared to other mastering methods.

### 2. CONFIGURATION OF APPARATUS FOR MANUFACTURING A MASTER DISC

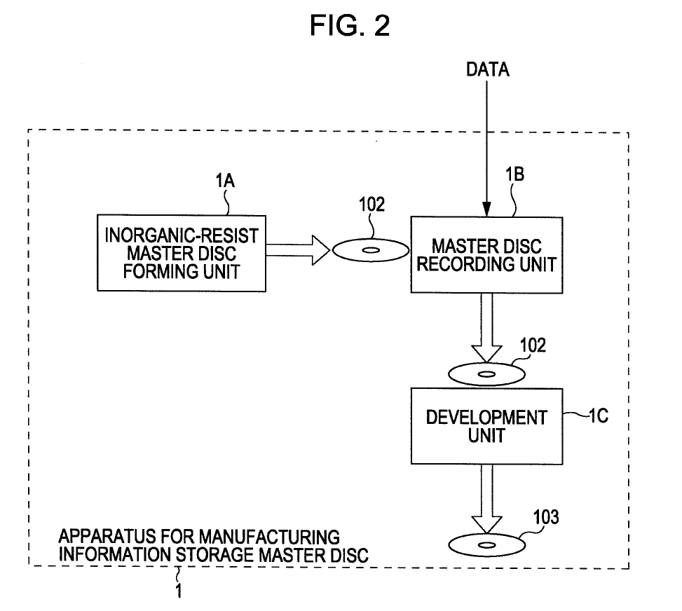

FIG. 2 shows an exemplary configuration of the apparatus for manufacturing an information storage master disc 1 according to an embodiment of the invention, which performs mastering by a PTM method. In the above-described mastering step shown in FIGS. 1C and 1D, the apparatus for manufacturing an information storage master disc 1 forms recording marks in the inorganic-resist master disc 102 having the inorganic resist layer 101 through a thermal recording operation by laser beam irradiation.

In FIG. 2, the apparatus for manufacturing an information storage master disc 1 includes an inorganic-resist master disc forming unit 1A, a master disc recording unit 1B, and a development unit 1C.

First, the inorganic-resist master disc forming unit 1A forms the inorganic-resist master disc 102 through the resist layer forming step shown in FIG. 1B.

A Si wafer, which serves as the master disc forming substrate 100, is loaded into the inorganic-resist master disc forming unit 1A from outside. An incomplete oxide of a transition metal, which is the material of the resist layer 101, is deposited on the Si wafer by means of sputtering.

When forming the above-mentioned intermediate layer 99, after the material of the intermediate layer 99 is deposited on the Si wafer, the resist layer 101 is deposited thereon.

The inorganic-resist master disc 102 formed by the inorganic-resist master disc forming unit 1A is transferred to the master disc recording unit 1B. The inorganic-resist master disc 102 is carried from the inorganic-resist master disc forming unit 1A to the master disc recording unit 1B by a handling robot (not shown) provided in the information storage medium generating apparatus 1. As will be described below, the inorganic-resist master disc 102 after being recorded (exposed) by the master disc recording unit 1B is carried to the development unit 1C by the handling robot.

The master disc recording unit 1B performs recording (exposure of the inorganic resist layer 101) by irradiating the inorganic-resist master disc 102 with a laser beam according to input data. When the inorganic-resist master disc 102 is irradiated with the laser beam, the property of the inorganic resist layer 101 deposited on the surface of the inorganic-resist master disc 102 is changed because of the heat of the laser beam. Thus, recording marks are formed.

The internal configuration and the recording (exposure) operation according to the present embodiment of the master disc recording unit 1B will be described below.

The development unit 1C performs the development step, as shown in FIG. 1D, on the inorganic-resist master disc 102 after going through the recording step by the master disc recording unit 1B to produce the master disc 103 as an information storage medium. More specifically, the inorganic-resist master disc 102 is immersed in a developing solution and is washed. Thus, the master disc 103 is produced.

In this development step, groove portions are formed at the exposed recording mark portions.

### 3. CONFIGURATION OF MASTER DISC RECORDING UNIT

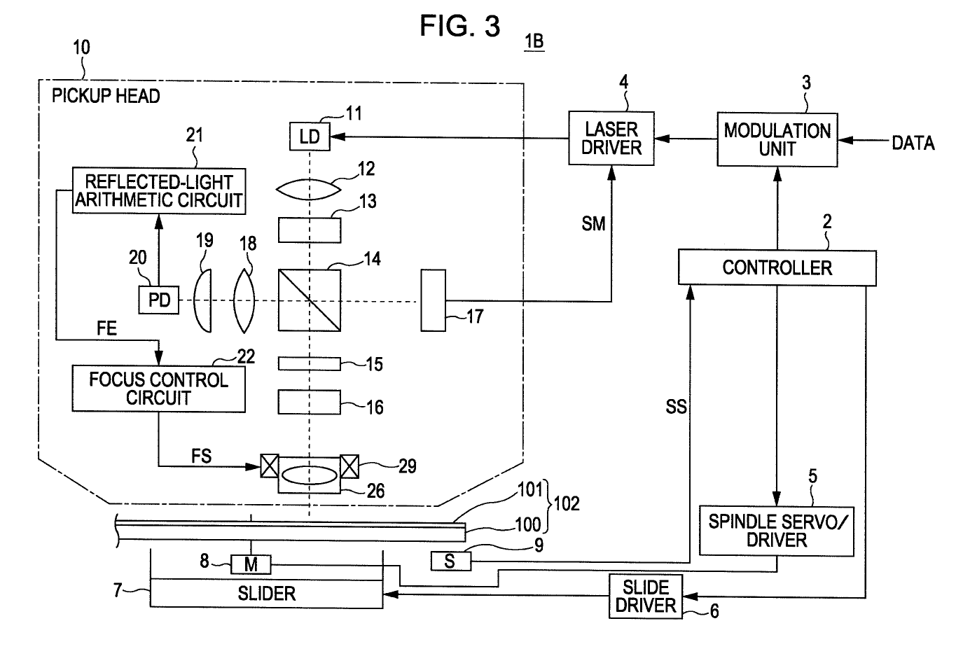

FIG. 3 shows an exemplary internal configuration of the master disc recording unit 1B shown in FIG. 2.

In FIG. 3, the master disc recording unit 1B has a pickup head 10, which is a structure enclosed by the alternate long and short dash line. In the pickup head 10, a laser beam source 11, which is a semiconductor laser, emits a blue-violet laser beam having a wavelength of 405 nm, for example.

The laser beam emitted from the laser beam source 11 is converted into a parallel beam by a collimator lens 12. The parallel beam is then changed into the laser beam whose spot shape is, for example, circular, by an anamorphic prism 13 and is directed to a polarizing beam splitter 14.

The polarized beam component leaving the polarizing beam splitter 14 passes through a λ/4 wavelength plate 14, a beam expander 16, and an objective lens 26 where the beam component is focused before being incident on the inorganic-resist master disc 102 (the master disc forming substrate 100 on which the inorganic resist layer 101 is formed).

The laser beam having a wavelength of 405 nm, which is emitted from the laser beam source 11 and is incident on the inorganic-resist master disc 102 through the objective lens 26, is focused on the inorganic resist layer 101 of the inorganic-resist master disc 102. When the inorganic resist layer 101 absorbs the laser beam having a wavelength of 405 nm, the central portion of the irradiated portion, heated to a high temperature, is polycrystallized.

Thus, an exposure pattern formed of groove portions is formed in the inorganic resist layer 101.

The polarized beam component reflected by the polarizing beam splitter 14 is incident on a monitor detector 17 (a photo detector for monitoring the laser power). The monitor detector 17 outputs a light intensity monitoring signal SM according to the light quantity level (light intensity) of the received light.

Returning light of the laser beam incident on the inorganic-resist master disc 102 passes through the objective lens 26, the beam expander 16, and the λ/4 wavelength plate 14 to the polarizing beam splitter 14. Because the laser beam passes through the λ/4 wavelength plate 14 twice, i.e., when it is incident on the inorganic-resist master disc 102 and when it returns therefrom, the plane of polarization is rotated by 90 degrees. Thus, the returning light is reflected by the polarizing beam splitter 14. The returning light reflected by the polarizing beam splitter 14 passes through a condenser lens 18 and a cylindrical lens 19 and is received by a light-receiving surface of a photo detector 20.

The light-receiving surface of the photo detector 20 is, for example, a quadrant light-receiving surface, and is capable of obtaining a focus error signal due to astigmatism.

Each light-receiving surface of the photo detector 20 outputs and supplies a current signal according to the received light intensity to a reflected-light arithmetic circuit 21.

The reflected-light arithmetic circuit 21 converts the current signal from each light-receiving surface of the quadrant light-receiving surface into a voltage signal, performs arithmetic processing as an astigmatism method to generate a focus error signal FE, and supplies the focus error signal FE to a focus control circuit 22.

The focus control circuit 22, according to the focus error signal FE, generates a servo drive signal FS for driving an actuator 29 that holds the objective lens 26 movably in a focus direction. Then, focus servo is performed by the actuator 29 driving the objective lens 26 to move close to or away from the inorganic-resist master disc 102 according to the servo drive signal FS.

The inorganic-resist master disc 102 is rotated by a spindle motor 8. The spindle motor 8 is rotated while the rotational speed thereof is controlled by a spindle servo/driver 5. Thus, the inorganic-resist master disc 102 is rotated at a constant linear velocity, for example.

A slider 7 is driven by a slide driver 6 to move the entire base including the spindle mechanism that carries the inorganic-resist master disc 102. That is, the inorganic-resist master disc 102 is exposed by the optical system while being rotated by the spindle motor 8 and moved by the slider 7 in the radial direction. As a result, groove portions (pit rows: tracks) are formed in a spiral shape in the inorganic resist layer 101.

The position moved by the slider 7, that is, the exposure position on the inorganic-resist master disc 102 (disc radial position: slider radial position) is detected by a sensor 9. Position detection information SS obtained by the sensor 9 is supplied to a controller 2.

The controller 2 controls the entire master disc recording unit 1B. For example, it controls the spindle-rotation operation of the spindle servo/driver 5 and the movement of the slider 7, performed by the slide driver 6, to control the recording position on the inorganic-resist master disc 102. Further, the controller 2 instructs the start of recording to a modulation unit 3, which will be described below.

The modulation unit 3, upon the receipt of the instruction from the controller 2, performs modulation processing for generating a recording driving signal whose amplitude is varied in three or more levels according to the input data.

The modulation processing performed by the modulation unit 3 according to the input data depends on the type of information to be recorded on the inorganic-resist master disc 102. A more specific example of the modulation processing will be described below.

The recording driving signal generated by the modulation unit 3 is input to a laser driver 4, and the laser driver 4 drives the above-described laser beam source 11 in the pickup head 10. The laser driver 4 applies a light emission driving current according to the recording driving signal to the laser beam source 11. As a result, the laser beam source 11 emits a laser beam with a certain light intensity corresponding to the signal whose amplitude is modulated in multiple levels (that is, three or more levels) according to the input data.

The light intensity monitoring signal SM is also supplied to the laser driver 4 from the monitor detector 17. The laser driver 4 can also perform laser light emission control on the basis of a result obtained by comparing the light intensity monitoring signal SM with the reference value.

In the master disc recording unit 1B according to the present embodiment, recording on the inorganic-resist master disc 102 is performed by irradiating the inorganic-resist master disc 102 with the laser beam having at least three power levels controlled according to the data to be recorded in the inorganic-resist master disc 102 (that is, the data to be stored in the optical disc serving as an information storage medium).

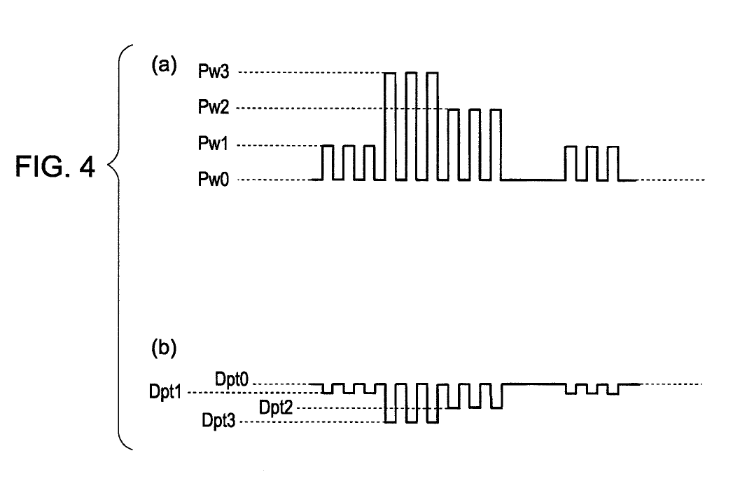

FIG. 4 shows an exemplary relationship between multi-step control of laser power (FIG. 4(a)) and the depths of groove portions formed in the inorganic-resist master disc 102 (master disc 103) (FIG. 4(b)). In FIG. 4(a), a laser power Pw0 shows a laser power that does not change the property of the inorganic resist layer 101. Laser powers Pw1 to Pw3 change the property of the inorganic resist layer 101, and the laser power increases from the laser power Pw1 to Pw3.

In FIG. 4(b), a depth Dpt0 shows land portions, and the depth of the groove portions increases from depths Dpt1 to Dpt3.

As is clear from the FIG. 4, by controlling the laser power Pw at multiple levels, the depth of the groove portions formed in the inorganic resist layer 101 is controlled at multiple levels according to the power Pw.

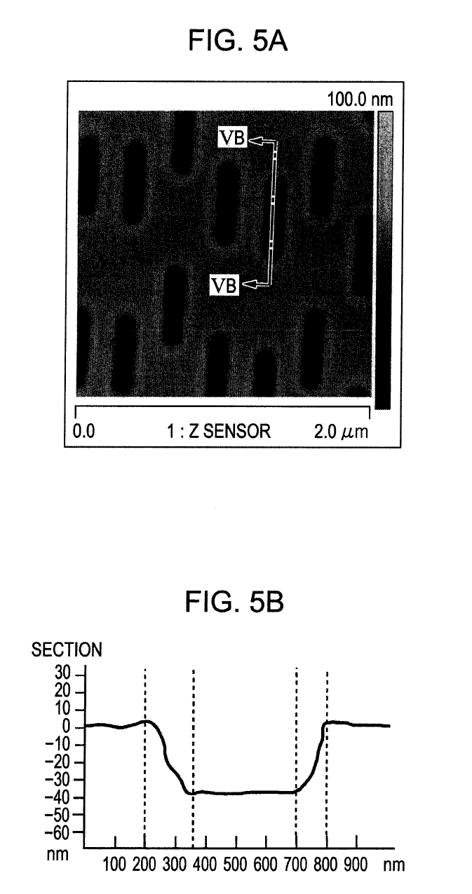

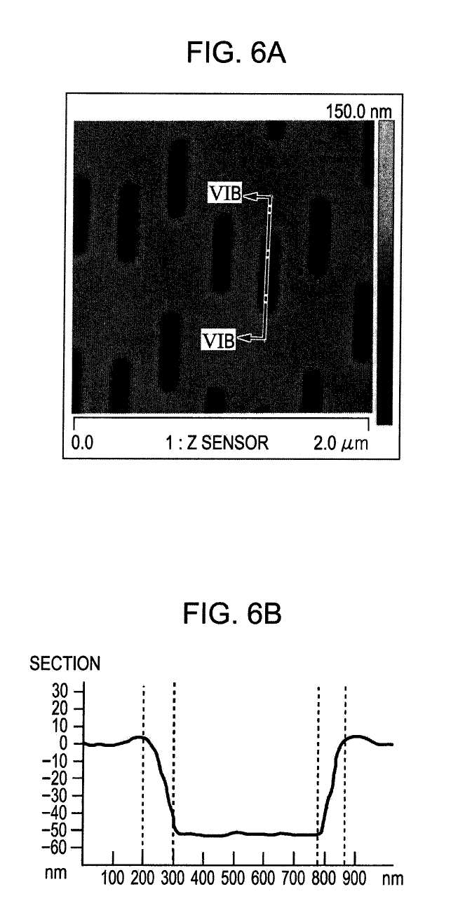

FIGS. 5A, 5B and 6A, 6B show groove portions resulted from actual experiments, formed when recording was performed using laser beams having different laser powers Pw. FIGS. 5A, 5B show the case where recording was performed with smaller power Pw, and FIGS. 6A, 6B show the case where recording was performed with greater power Pw. FIGS. 5A and 6A show the results of the observation of the surface of the inorganic resist layer 101 using an electron microscope, and FIGS. 5B and 6B show the cross sections of the groove portions. FIG. 5B shows a cross sectional view taken along line VB-VB shown in FIG. 5A, and FIG. 6B shows a cross sectional view taken along line VIB-VIB shown in FIG. 6A.

By comparing these drawings, it can be understood that the depth of the grooves formed in the inorganic resist layer 101 can be controlled in steps according to the power of the laser beam emitted.

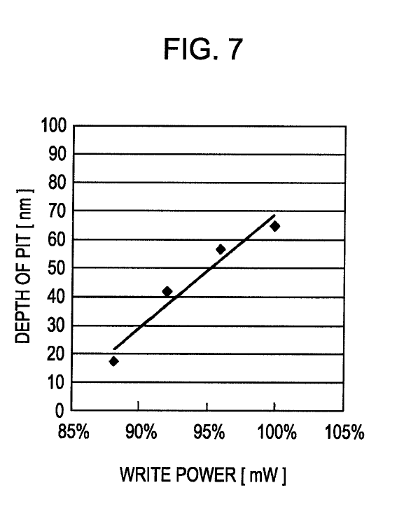

FIG. 7 is the graph showing the relationship between the laser power (abscissa) and the depth of a resulting groove portion (ordinate), based on an actual experiment.

The plot points in FIG. 7 represent the results when the power Pw is 100%, 96%, 92%, and 88%. More specifically, when the power Pw was 100%, the depth of the groove Dpt was 65.0 nm, when the power Pw was 96%, the depth of the groove Dpt was 56.4 nm, when the power Pw was 92%, the depth of the groove Dpt was 41.6 nm, and when the power Pw was 88%, the depth of the groove Dpt was 17.4 nm.

These experimental results show the depth of the groove Dpt changes substantially in proportion to the power Pw. That is, from this result, it can be understood that the depth of the grooves can be controlled in steps in accordance with the power of the laser beam emitted, and that the depth of the grooves can be changed substantially linearly in accordance with changes in power.

As has been described, in the present embodiment, in addition to a PTM method being employed in manufacturing the master disc 103 serving as an information storage master disc, in recording a master disc, the laser beam is emitted while the power Pw is varied over multiple levels in accordance with the input data. Thus, groove portions having at least two levels of depth can be formed in the inorganic-resist master disc 102. That is, multi-level recording, including land portions, in the depth direction can be performed.

By making it possible to perform information recording in the depth direction too, the storage capacity of the optical disc serving as an information storage medium can be increased.

According to the present embodiment, when information recording is performed utilizing the depth of the grooves, it is not necessary to provide multiple resist layers as in the case of the related art. Therefore, unlike the related art, it is not necessary to employ a method in which film deposition and etching are alternately performed or a method in which a plurality of resist layers having different sensitivities are deposited. Accordingly, the initial cost, running cost, and labor cost associated with the manufacturing apparatus can be reduced. In addition, because the operation time of the apparatus is reduced, strain on the environment is minimized.

In addition, according to the present embodiment, formation of groove portions (concave-convex pattern) with multiple depths is carried out in a single step (exposure step). Therefore, degradation in dimensional accuracy due to misalignment of the mask, which was described as a problem occurring in the related art method, does not occur, and a more precise recording can be performed.

Furthermore, exposure does not have to be performed in a special environment such as a vacuum state, and it may be performed in a normal atmospheric environment. Therefore, unlike the related art method in which the acceleration voltage is varied, the problem that the size of substrates is limited does not occur. Accordingly, it becomes possible to manufacture a large-area storage medium.

In addition, the present embodiment has an advantage in that a material that poses a high risk to human bodies and the environment does not have to be used as an inorganic resist film or a developing solution.

Furthermore, the use of a PTM method enables formation of finer grooves.

More specifically, in the present embodiment, laser beam irradiation is performed under a condition in which the wavelength, λ, of the laser beam is 405 nm and the numerical aperture, NA, of the objective lens 26 is about 0.85. The width of grooves is substantially the same as that in BDs.

In addition, according to the present embodiment, an incomplete oxide of a transition metal is used as the inorganic resist layer 101. Because an incomplete oxide of a transition metal is conductive, when forming the metal master disc (stamper 104), the master disc 103 can be directly electroformed.

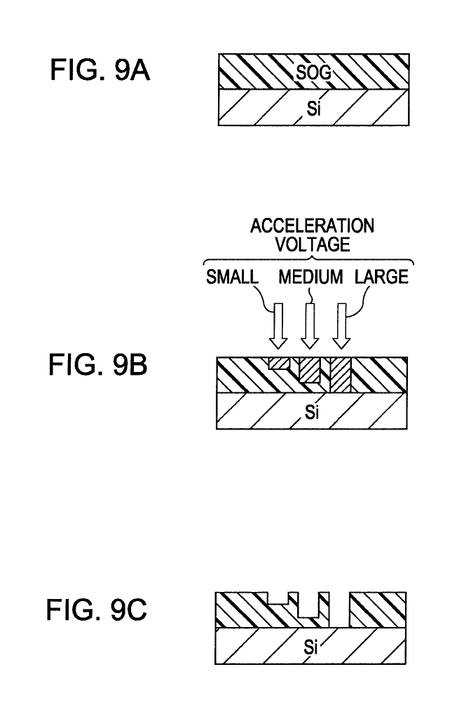

In the related art method explained with reference to FIGS. 9A to 9C, the SOG was used as an inorganic resist material. However, because the SOG is mainly composed of silicon dioxide (SiO₂), it is not conductive. Therefore, in forming a metal stamper, a conductive film has to be deposited. That is, the method according to the present embodiment can eliminate an extra process which had to be performed in the related art method to form a metal stamper.

### 4. EXEMPLARY MODULATION PROCESSING

To increase the storage capacity by employing information recording utilizing the depths of grooves, input data have to be modulated according to a method different from a recording method used in a typical optical disc.

If it is possible to make the depths of grooves different from each other, recording using multilevel code becomes possible. Accordingly, a binary-to-multilevel conversion may be performed on the input data as modulation processing. In other words, a data sequence, serving as input data, including a combination of binary codes, i.e., 0 and 1, may be converted to a data sequence including a combination of multilevel codes, i.e., ternary or higher-level codes.

For example, regarding a binary data sequence, let us consider a case where one symbol of encoding includes four bits, that is, the case where four bits of the binary code, such as “0001”, “0010”, or “0011”, constitute one symbol.

In the case where one symbol includes four bits of the binary code, the number of combinations of binary codes is 4², i.e., 16.

On the other hand, if the number of depths of grooves formed by the laser power control according to the present embodiment is four, namely, Dpt 0 to Dpt 3, including a land portion, recording using four-level codes (herein temporarily, “0, 1, 2, and 3”) becomes possible. It is desirable that the 16 combinations be expressed using these four-level codes.

To obtain 16 patterns using four-level codes, one symbol may include two bits. That is, by making two bits of the four-level code represent one symbol, similarly to the above case, it is possible to express 16 patterns, by 4².

Thus, for example, by making the number of levels of depth of grooves four and enabling recording with four-level codes, compared to the typical recording with the binary codes, the number of bits necessary for recording the same amount of data (that is, the necessary space) can be reduced to half. In other words, the storage capacity can be doubled.

As is clear from this, in recording using grooves of a plurality of depths, if multilevel (at least ternary) recording is possible, the number of bits necessary for recording the same amount of input data can be reduced. As a result, compared to the typical recording binary recording using only pits and lands, the storage capacity is increased.

To increase the storage capacity, the modulation unit 3 shown in FIG. 3 performs the above-described binary-to-multilevel code conversion. A conversion table (look-up table) for performing binary-to-multilevel code conversion is stored in the modulation unit 3. A binary input data sequence is converted to a multilevel code sequence on a predetermined bit number basis (that is, per symbol), according to the conversion table. Then, a recording driving signal whose amplitude level is changed according to the code value of each multilevel code sequence obtained by the conversion is generated, and the recording driving signal is supplied to the laser driver 4.

Modulation processing performed by the modulation unit 3 on the input data realizes a recording operation for increasing the storage capacity.

The recording method for increasing the storage capacity is not limited to the above-described method.

To increase the storage capacity, at least, recording may be performed while the position of the rotated inorganic-resist master disc 102 irradiated with the laser beam is sequentially shifted in the radial direction and while the power of the laser beam is varied over multiple levels according to the input data.

### 5. MODIFICATION EXAMPLE

Although the embodiments of the present invention have been described, the present invention is not to be limited to the above-described specific examples.

For example, although the case in which multilevel recording is performed by differentiating the depths of grooves has been described, if it is possible to differentiate the depths of grooves, it is possible to record an image as a hologram.

When recording a hologram image, two-dimensional image data as input data is input to the modulation unit 3. Such image data to be input may be the data specifying the gradation value on a pixel-by-pixel basis. As has been described above, when a hologram image is recorded, it is desirable that about 16 gradations be expressed, for example. Thus, let us assume that the gradation values of the pixels of the image data to be input to the modulation unit 3 include, for example, about 16 gradation values.

In this case, the modulation unit 3 generates recording driving signals whose amplitude levels have been changed according to the gradation values of the pixels of the input image data.

In this case, in recording the image data, a laser beam is sequentially scanned for each line of the image data. Therefore, the modulation unit 3 generates, for each line of the image data, the recording driving signals whose amplitude levels have been sequentially changed according to the gradation values of the pixels.

The controller 2 instructs the slide driver 6 and controls the slide operation of the inorganic-resist master disc 102 performed by the slider 7, so as to allow the laser beam to be scanned in a line-sequential manner, as described above.

The modulation processing by the modulation unit 3 and the slide control by the controller 2 make it possible to record a hologram image on a predetermined area of the inorganic-resist master disc 102.

As is clear from the description given above, it is not necessary to rotate the inorganic-resist master disc 102 when a hologram image is to be recorded. Therefore, the structure for rotating the master disc (spindle servo/driver 5 and spindle motor 8), as shown in FIG. 3, may be omitted.

As has been described, the PTM method according to the present embodiment enables microprocessing of grooves. Accordingly, when an image serving as an encrypted pattern, for example, is recorded as a hologram image, it is possible to record a fine pattern that is very difficult to be counterfeited. Such hologram images are suitable for preventing credit cards, licenses, various certificates, etc., from being counterfeited.

When a hologram is recorded, it is possible to perform recording not such that the formed image has a meaning, but such that necessary data, such as music or video content, are recorded. That is, information may be recorded as a hologram memory (holographic memory).

In the case of a hologram memory, a difference in the levels of groove portions to be formed produces a difference in the optical path lengths of incident light emitted during play back. A stored value is identified by a phase difference produced by such a difference in the optical path lengths. That is, in the case of a hologram memory, information may be recorded by giving at least three or more levels, i.e., depth dpt=0, 1, and 2, of phase differences among pixels.

In this case, a binary data sequence is input to the modulation unit 3 as information to be stored. Then, as described above, the binary data sequence is converted to a multilevel data sequence. Then, each value of the multilevel data sequence is mapped as a pixel value of a hologram page of the necessary pixel size, and data as a hologram image is generated. After the hologram image is obtained, recording operation similar to the above-described hologram-image recording operation may be performed.

Alternatively, when a hologram memory is manufactured, it is possible to configure such that recording on a per-hologram page basis is performed by laser beam irradiation through a spatial light modulator (SLM) inserted in the optical system in the pickup head 10.

In this case, for example, a liquid crystal panel is used as the SLM. The SLM having a size (pixels) at least sufficient to cover (display) the hologram page is used.

In this case, power control of the laser beam is performed not by controlling the laser driver 4 with the recording driving signal but by controlling the transmissivity of each pixel of the SLM. That is, the modulation unit 3 controls driving (display) of the SLM according to the hologram image produced in the modulation processing and makes the inorganic-resist master disc 102 be irradiated with the image generated by optical intensity modulation (that is, laser power control) of the SLM. Thus, irradiation with a laser beam whose light intensity for each pixel is controlled over three or more levels becomes possible. As a result, it becomes possible to record an image expressed by concaves and convexes with multiple levels of depth.

It is to be noted that, in this configuration too, during recording (exposure), a laser beam is emitted whose power is varied over three or more levels according to the input data.

In the above description, an exemplary case has been described in which the inorganic resist layer 101 is made of an incomplete oxide of a transition metal. However, as long as a material reactive to thermal reaction associated with laser beam irradiation is selected, control of the depth of grooves may be performed by controlling laser power over multiple levels while the width of the grooves is limited to a certain value (that is, while microprocessing is enabled), compared to the case in which a typical resist material for optical recording, such as a photoresist, is used.

In the above description, an exemplary case has been described in which the depths of grooves are differentiated to record data, such as music content or video content, and a hologram image. However, the present invention is suitably used to differentiate the levels of grooves by continuous laser beam irradiation.

It should be understood by those skilled in the art that various modifications, combinations, sub-combinations and alterations may occur depending on design requirements and other factors insofar as they are within the scope of the appended claims or the equivalents thereof.

What is claimed is:

1. A method for manufacturing an information storage medium in which information is stored as a concave-convex pattern, the method comprising the steps of:
forming an inorganic-resist master disc by depositing on a substrate an inorganic resist layer reactive to thermal reaction associated with laser beam irradiation;
recording on the inorganic-resist master disc by differentiating depths of thermal reaction portions in the inorganic resist layer by inputting information to be stored in the information storage medium and varying power of the laser beam striking the inorganic-resist master disc over at least three levels according to the input information;
forming an information storage master disc having a concave-convex pattern in the inorganic resist layer by developing the inorganic-resist master disc having been recorded in the recording step;
forming a stamper to which the concave-convex pattern formed on the inorganic resist layer has been transferred on the basis of the information storage master disc; and
forming the information storage medium using the stamper formed in the stamper forming step.

2. The method according to claim 1,
wherein, in the inorganic-resist master disc forming step, an incomplete oxide of a transition metal is deposited as the inorganic resist layer.

3. The method according to claim 2,
wherein, in the recording step, a blue-violet laser beam is used as the laser beam.

4. The method according to claim 1,
wherein, in the recording step, recording is performed on the rotated inorganic-resist master disc while the position at which the laser beam strikes the inorganic-resist master disc is sequentially shifted in the radial direction.

5. The method according to claim 1,
wherein, in the recording step, image data is input as the information, and the laser beam is scanned line-sequentially according to the input image data.

6. An apparatus for manufacturing an information storage master disc used to manufacture an information storage medium in which information is stored as a concave-convex pattern, using an inorganic-resist master disc formed by depositing on a substrate an inorganic resist layer reactive to thermal reaction associated with laser beam irradiation, the apparatus comprising:
laser irradiation means that irradiates the inorganic resist layer of the inorganic-resist master disc with the laser beam;
recording means that performs recording on the inorganic-resist master disc by differentiating depths of thermal reaction portions in the inorganic resist layer by inputting information to be stored in the information storage medium and varying power of the laser beam striking the inorganic-resist master disc over at least three levels according to the input information; and
information storage master disc forming means that forms the information storage master disc having a concave-convex pattern in the inorganic resist layer by developing the inorganic-resist master disc having been recorded by the recording means.

7. An apparatus for manufacturing an information storage master disc used to manufacture an information storage medium in which information is stored as a concave-convex pattern, using an inorganic-resist master disc formed by depositing on a substrate an inorganic resist layer reactive to thermal reaction associated with laser beam irradiation, the apparatus comprising:
a laser irradiation unit that irradiates the inorganic resist layer of the inorganic-resist master disc with the laser beam;
a recording unit that performs recording on the inorganic-resist master disc by differentiating depths of thermal reaction portions in the inorganic resist layer by inputting information to be stored in the information storage medium and varying power of the laser beam striking the inorganic-resist master disc over at least three levels according to the input information; and
an information storage master disc forming unit that forms the information storage master disc having a concave-convex pattern in the inorganic resist layer by developing the inorganic-resist master disc having been recorded by the recording unit.
